(19) United States
(12) Patent Application Publication
(10) Pub. No.: US 2013/0146141 A1
(43) Pub. Date: Jun. 13, 2013

(54) SMALL CORE/LARGE SHELL SEMICONDUCTOR NANOCRYSTALS FOR HIGH PERFORMANCE LUMINESCENT SOLAR CONCENTRATORS AND WAVELENGTH DOWNSHIFTING

(71) Applicants: Matthew A. PELTON, Chicago, IL (US); Elena SHEVCHENKO, Riverside, IL (US); Seth B. DARLING, Chicago, IL (US); Roy J. HOLT, Western Springs, IL (US); David H. POTTERVELD, Oak Park, IL (US)

(72) Inventors: Matthew A. PELTON, Chicago, IL (US); Elena SHEVCHENKO, Riverside, IL (US); Seth B. DARLING, Chicago, IL (US); Roy J. HOLT, Western Springs, IL (US); David H. POTTERVELD, Oak Park, IL (US)

(21) Appl. No.: 13/711,383

(22) Filed: Dec. 11, 2012

Related U.S. Application Data
(60) Provisional application No. 61/569,567, filed on Dec. 12, 2011.

(51) Int. Cl. G01T 1/20; H01L 31/055

(52) U.S. Cl. CPC G01T 1/20; H01L 31/055; G01T 1/2006
USPC 136/259; 250/483.1; 250/361 R

(57) ABSTRACT

An article of manufacture and method for making a luminescent solar concentrator or a wavelength shifting device. The article includes a light guide or optical medium with a luminescent material disposed therein or deposited on the surface. The luminescent material is formulated to absorb incoming radiation and wavelength shift that radiation to a larger wavelength for processing and use, and to minimize reabsorption of the shifted radiation by the luminescent material.

### CROSS-REFERENCE TO RELATED PATENT APPLICATIONS

This application claims priority from Provisional Application U.S. Application 61/569,567, filed Dec. 12, 2011, incorporated herein by reference in its entirety.

### STATEMENT OF GOVERNMENT INTEREST

The United States Government has rights in the invention described herein pursuant to Contract No. DE-AC02-06CH11357 between the United States Department of Energy and UChicago Argonne, LLC, as operator of Argonne National Laboratory.

### BACKGROUND OF THE INVENTION

The invention relates to articles of manufacture and methods of assembling and using small core/large shell semiconductor nanocrystals. More particularly, this invention relates to small core/large shell geometries of nanocrystals for providing articles of manufacture and methods of use as high performance, luminescent solar concentrators and for other applications, such as wavelength downshifting devices for other electronic, opto-electronic and optical applications, such as broadening wavelength detection range of photodetectors, including imaging detectors, serving as active material in scintillation detectors and also for use as biological labels.

The challenge facing solar energy is concerned primarily with the relatively diffuse nature of the sun as an energy source, which means that large areas must be covered by expensive photovoltaic (PV) devices in order to collect sufficient light. Solar concentrators reduce the required PV area by collecting solar radiation from a large area and redirecting it onto a smaller PV device. Luminescent solar concentrators (LSCs), in particular, have the potential to be fabricated and operated at low cost, and can operate in diffuse and indirect sunlight. Semiconductor nanocrystals (NCs) are the most promising substitutes for organic dyes, providing efficient emission at near-infrared wavelengths. The performance of LSCs incorporating typical semiconductor NCs is currently limited, though, by reabsorption of emitted light. In an LSC, a luminescent material is embedded in or deposited on a transparent optical waveguide which luminescent material absorbs incident sunlight and re-emits at a longer wavelength. The emitted light is trapped in the waveguide by total internal reflection (TIR) and is thereby directed towards a high efficiency PV device on the edge of the light guide. Performance of an LSC is limited by loss of the emitted light. Reabsorption of the emitted light by the luminescent material increases the amount of optical loss and is often the limiting factor determining the efficiency and degree of concentration that can be obtained. Efficient employment of LSCs also requires materials that absorb and emit at near-infrared wavelengths, in order to optimize use of the solar spectrum.

LSC materials that emit visible light have been widely studied, but the availability of suitable materials that emit near-infrared light has been very limited. Studies of LSCs have generally relied on small organic molecules, which can have high luminescence quantum yields, but which usually have absorption spectra that overlap significantly with their emission spectra, leading to strong reabsorption of the emitted light. In addition, these materials usually suffer from limited stability, undergoing rapid photobleaching in sunlight. Recently, molecular design techniques have made it possible to overcome reabsorption issues and greatly improve stability. However, the photoluminescence efficiency of dyes drops rapidly as their emission wavelength increases, and virtually no practical dyes exist with emission wavelengths longer than 1000 nm.

### SUMMARY OF THE INVENTION

Semiconductor nanocrystals (NCs) are the most promising substitutes for organic dyes, providing efficient emission at near-infrared wavelengths. The performance of LSCs incorporating typical semiconductor NCs is currently limited, though, by reabsorption of emitted light. Our invention is directed to NC structures that can emit at near-infrared wavelengths and exhibit low reabsorption. This is enabled by heterostructure NCs that have a large shell of higher-bandgap semiconductor material coupled to a much smaller emissive core of smaller-bandgap material. The shell acts as an absorbing antenna, efficiently harvesting solar energy and funneling it to the emissive core. By dramatically increasing the amount of material in the shell compared to the core, these materials significantly mitigate reabsorption of emitted light.

These materials can also be advantageous for other applications that involve absorption of light and emission at a lower wavelength where it is important to minimize reabsorption of the emitted light. For example, transparent matrices containing the NCs, similar to those used to fabricate the LSCs, could serve as wavelength-shifting materials for solar cells and photodetectors, including imaging photodetectors such as CCD cameras. The luminescent materials would absorb light at wavelengths that are normally not absorbed by the detector or solar cell and re-emit at a wavelength that is absorbed by the detector or solar cell. This would effectively extend the wavelength range of the device; however, if the luminescent material has significant absorption at wavelengths that are normally absorbed by the detector or solar cell, then this will reduce the efficiency of the device. Because of their minimal reabsorption, the small core/large-shell NCs are thus well suited to these applications. The NCs could also be used to downconvert much higher-energy ionizing radiation, such as X-rays, to visible or near-infrared wavelengths, serving as the material in a scintillation detector. Once again, minimal reabsorption at the emission wavelength is crucial for efficient operation of such detectors.

Herein, chemical synthesis of NC heterostructures is shown and includes embodiments with small cores within a larger, rod-shaped shell. It is demonstrated that absorption of a photon by the NC shell is followed by rapid transfer of photoexcited carriers to the NC core and emission of a lower-energy photon, allowing for high-efficiency luminescence with small reabsorption of the emitted light. These measurements indicate that the luminescence properties of these nanocrystals are dictated substantially by the volume of the particle, meaning that nanocrystals with different-shaped shells can be investigated for the fabrication of high-quality LSCs. These NCs emit at visible wavelengths, and can be extended to small-core/large-shell NCs based on other materials, including but not limited to heavy metal chalcogenide core/shell pairs like PbTe/PbS and PbSe/PbS, that emit at near-infrared wavelengths.

These and other advantages and features of the invention, together with the organization and manner of operation thereof, will become apparent from the following Detailed Description when taken in conjunction with the accompanying drawings.

### BRIEF DESCRIPTION OF THE DRAWINGS

FIG. 1A shows a solar concentrator with a luminescent material disposed in (or can be disposed on) a light guide to direct collected light emitted from the luminescent material to a photovoltaic cell; FIGS. 1B(1)-1B(3) schematically show spectra for sunlight absorption and re-emission at longer wavelength in the light, and illustrate trapping of the emitted light by total internal reflection (TIR) and absorption by a photovoltaic cell disposed on an edge of the light guide; FIGS. 1C(1)-1C(4) show a sequence of solar radiation absorption and re-emission by a small core/large shell nanocrystal system;

FIG. 2 shows absorption efficiency versus emission energy for a lower layer of a semiconductor nanocrystal luminescent solar concentrator (LSC);

FIG. 3A shows a single small core/large shell nanocrystal for a preferred form of the LSC; FIG. 3B shows a light guide containing a plurality of the nanocrystals of FIG. 3A; and FIG. 3C shows a schematic of a camera with a coating containing luminescent material;

FIGS. 4A-4D show transmission electron microscope images of CdSe/CdS core/shell nanorods with 2.0 nm CdSe cores with nanorod “shell” lengths of 9, 18, 41 and 70 nm corresponding to rod volumes, V, of 60, 180, 500, and 1540 nm³, respectively; FIG. 4E shows optical absorption spectra for nanorods with different volumes and the inset shows a magnified view of the absorption in the energy region from 2.1 to 2.5 eV; and FIG. 4F shows a contour plot of emission spectra for nanorods with different rod volumes; and the color scale represents normalized emission intensity;

FIG. 5 shows an example prototype device with nanocrystals incorporated into polymer slabs serving as light guides;

FIG. 6 shows quantum yield (QY) as a function of nanorod volume for CdSe/CdS core/shell nanorods with different core sizes (2.0, 4.0, and 5.0 nm), obtained by exciting the shell with a photon energy of 2.76 eV (450 nm);

FIG. 7A shows a schematic sketch of the proposed quasi-type-II band alignment in CdSe/CdS core/shell nanorods and possible processes following above-band optical excitation: (1) carrier relaxation, (2) hole transfer to the CdSe core, (3) carrier trapping, (4) nonradiative recombination, and (5) radiative recombination; effective CdS and CdSe band gap energies depend on the nanorod dimensions and the values given are representative; and FIG. 7B shows photoluminescence decays for CdSe/CdS core/shell nanorods with 2.0 nm cores and different rod volumes, V; and the green solid lines are exponential fits to the decays, shown in order to illustrate the small deviation of the measured data from single-exponential decay;

FIG. 8A shows relative radiative decay rates, Γᵣ, as a function of nanorod volume for CdSe/CdS core/shell nanorods with different sizes of CdSe cores; and FIG. 8B shows nonradiative decay rates, Γₙᵣ, as a function of nanorod surface area for the same nanorod samples;

FIG. 9A shows transient absorption spectra of example systems of CdSe/CdS core/shell nanorods with 2.0 nm cores and 180 nm³ volumes, following excitation with a photon energy of 3.10 eV (400 nm); FIG. 9B shows transient absorption kinetics for CdSe/CdS core/shell nanorods with 2.0 nm cores and different volumes; the inset shows the same data over a longer time range; the probe energies are 2.26, 2.22, and 2.17 eV for nanorod volumes of 110, 180 and 1540 nm³, respectively, all of which correspond to the CdSe bleach minima; and also shown are the kinetics for CdSe nanoparticles, with no CdS shell.

FIGS. 10A-10C show distribution of volumes of an example system of CdSe/CdS core/shell nanorods with different sizes of CdSe cores, after 5 minutes of CdS shell growth; bars are measured values, and dashed lines are lognormal fits; FIG. 10A is for a 2.0 nm core and average volume=500 nm³, standard deviation=6%, FIG. 10B is for a 4.0 nm core, and an average volume=1250 nm³, standard deviation=13%, FIG. 10C is for a 5.0 nm core, and an average volume=660 nm³, standard deviation=18%;

FIGS. 11A and 11B shows a sample absorption spectra of CdSe/CdS core/shell nanorods with 4.0 nm (FIG. 11A) and 5.0 nm (FIG. 11B) CdSe cores; spectra are shown for different nanorod volumes, V;

FIGS. 12A and 12B show contour plots of emission spectra for CdSe/CdS core/shell nanorods with 4.0 nm (FIG. 12A) and 5.0 nm (FIG. 12B) CdSe cores; excitation is at 2.76 eV (450 nm);

FIGS. 13A and 13B show photoluminescence decay kinetics for CdSe/CdS core/shell nanorods with 4.0 nm (FIG. 13A) and 5.0 nm (FIG. 13B) CdSe cores; excitation is at 3.10 eV (400 nm) and results are shown for different nanorod volumes, V;

FIGS. 14A and 14B show radiative decay rates as a function of aspect ratio (FIG. 14A) and length (FIG. 14B) for CdSe/CdS core/shell nanorods; excitation is at 2.76 eV (450 nm);

FIGS. 15A and 15B show transient absorption spectra for CdS nanorods (FIG. 15A) and spherical CdSe nanoparticles with 2.0 nm diameter (FIG. 15B); excitation is at 3.10 eV (400 nm);

FIG. 16 shows transient-absorption kinetics, monitored at the CdS band edge, for CdSe/CdS core/shell nanorods with 2.0-nm cores and different volumes, V, and for CdS nanorods; the kinetics correspond to population of electrons at the edge of the CdS conduction band and excitation is at 3.10 eV (400 nm);

FIGS. 17A and 17B show transient-absorption kinetics, measured at the CdSe band edge, for CdSe/CdS core/shell nanorods with 4.0 nm (FIG. 17A) and 5.0 nm (FIG. 17B) CdSe cores; results are reported for different nanorod volumes, V, and the kinetics correspond to transfer of holes from the CdS shells to the CdSe cores; the points are experimental data, and the lines are exponential fits, with a rise time of 0.57±0.05 ps; and

FIGS. 18A-18F show TEM images of CdSe/CdS core/shell nanorods with different sizes of CdSe cores and lengths (L) of CdS shells; FIG. 18A is for 2.0 nm core, L=23 nm; FIG. 18B is for 4.0 nm core, L=27 nm; FIG. 18C is for 5.0 nm core L=45 nm; FIGS. 18D-18F are TEM images of the three CdSe cores, with FIG. 18D for 2.0 nm CdSe core; FIG. 18E for 4.0 nm CdSe core; and 18F for 2.0 nm CdSe core.

### DETAILED DESCRIPTION OF PREFERRED EMBODIMENTS

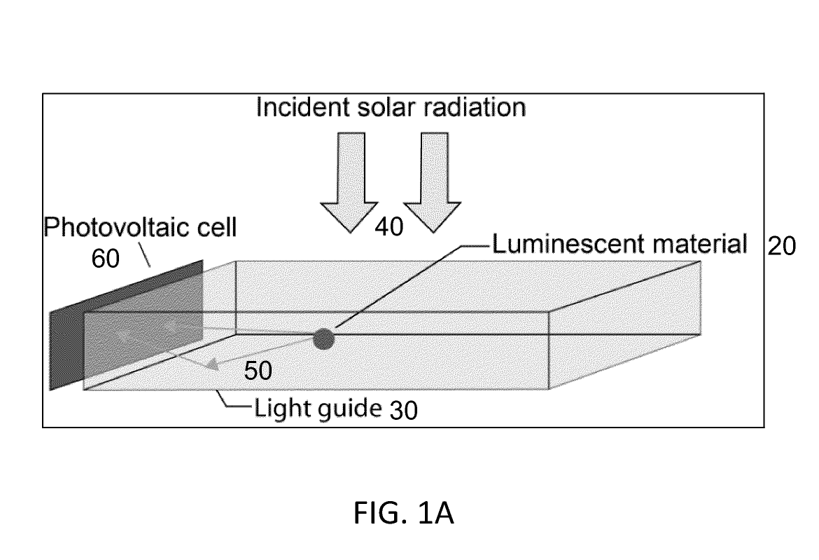

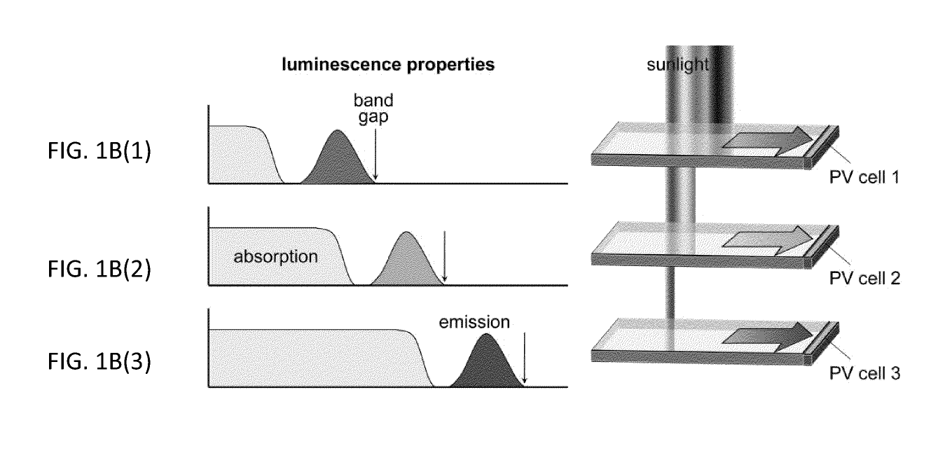

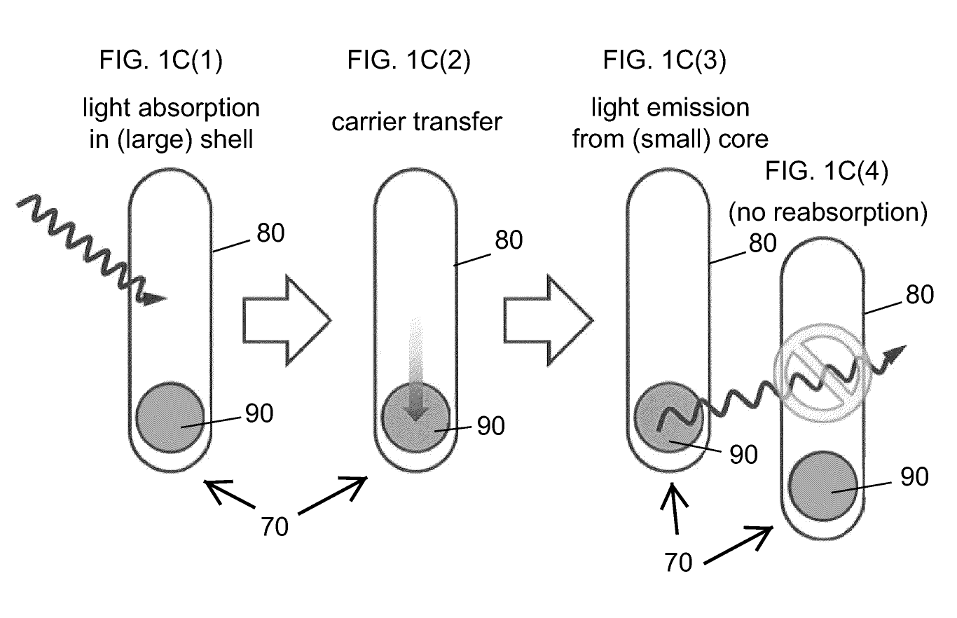

In a preferred embodiment a luminescent solar concentrator (LSC) 10 is shown in FIG. 1A and includes a luminescent material 20 within a slab of material with a high refractive index serving as a light guide 30. Incident solar radiation 40 is absorbed by the luminescent material 20, which subsequently emits light 50 with a longer wavelength. The majority of this light 50 is trapped within the light guide 30 by total internal reflection, and directed towards one side of the slab, where a photovoltaic cell 60 is placed. The performance of the LSC 10 is limited by any reabsorption of the emitted light 50 by the luminescent material 20. An alternative embodiment would have the luminescent material 20 deposited on a thin metal on the top surface of the light guide 30.

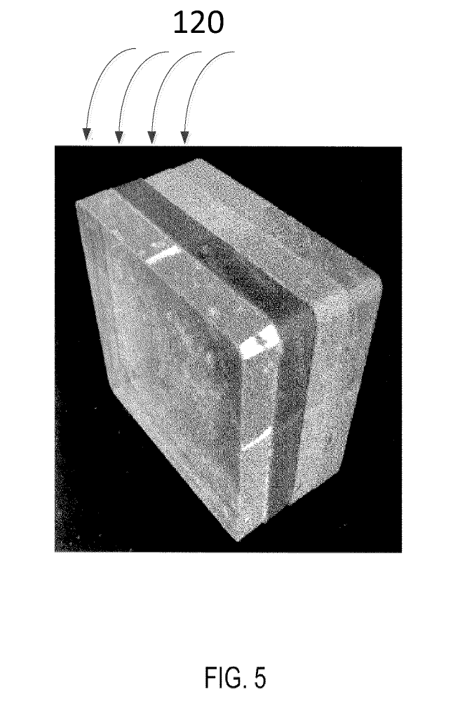

In FIGS. 1A and 1B, the LSC 10 incorporates the selected luminescent material 20 and slabs of the basic LSC 10 are preferably stacked, one above the other (see FIG. 5). The material 20 in each lower layer is designed to absorb part of the spectrum of the solar radiation 40 that is not absorbed by one of the upper layers. The photovoltaic cells 60 on each stage are customized so that they are maximally efficient for the wavelength of the light 50 emitted by the luminescent material 20 for that slab of the LSC 10. In this way, the different wavelengths in the solar radiation 40 can be most efficiently used. In FIGS. 1B(1)-1B(3) are shown the various stages of processing the solar radiation 40. In FIG. 1B(1) the absorption and emission spectra are shown for the luminescent material 20 in the top stack. The absorbed solar radiation portion 40 is shown as a gray area which is absorbed by the luminescent material 20. The peak in FIG. 1B(1) represents the wavelength range of light emitted by the luminescent material 20 in the top layer. A substantial fraction of this radiation is trapped by total internal reflection (TIR) in the light guide 30 in that layer and then absorbed by the photovoltaic cell 60. The portion of the solar radiation that is not absorbed by the top layer passes through to the second layer in the stack, illustrated in FIG. 1B(2). Some of this radiation, shown by the gray area, is absorbed in this layer and is emitted at longer wavelengths, shown by the peak. The light that is not absorbed by either of the top two layers passes through and is absorbed by the bottom layer, FIG. 1B(3). In this way, each layer in the stack efficiently uses a portion of the total solar spectrum, allowing for efficient overall conversion.

FIGS. 1C(1)-1C(4) show a preferred structure 70 of the luminescent material 20. This structure 70 comprises a large shell 80 wherein the solar radiation 40 is efficiently absorbed as in FIG. 1C(1). Electronic carriers (electrons and holes) in FIG. 1C(2) created by the absorption are transferred to a small core 90 which emits the light 50 at a lower energy or longer wavelength than the solar radiation (see FIG. 1C(3)). Because the amount of the core luminescent material 20 is much less than the amount of shell material, reabsorption is limited and enables efficient conversion of light by the LSC 10 (see FIG. 1C(4)).

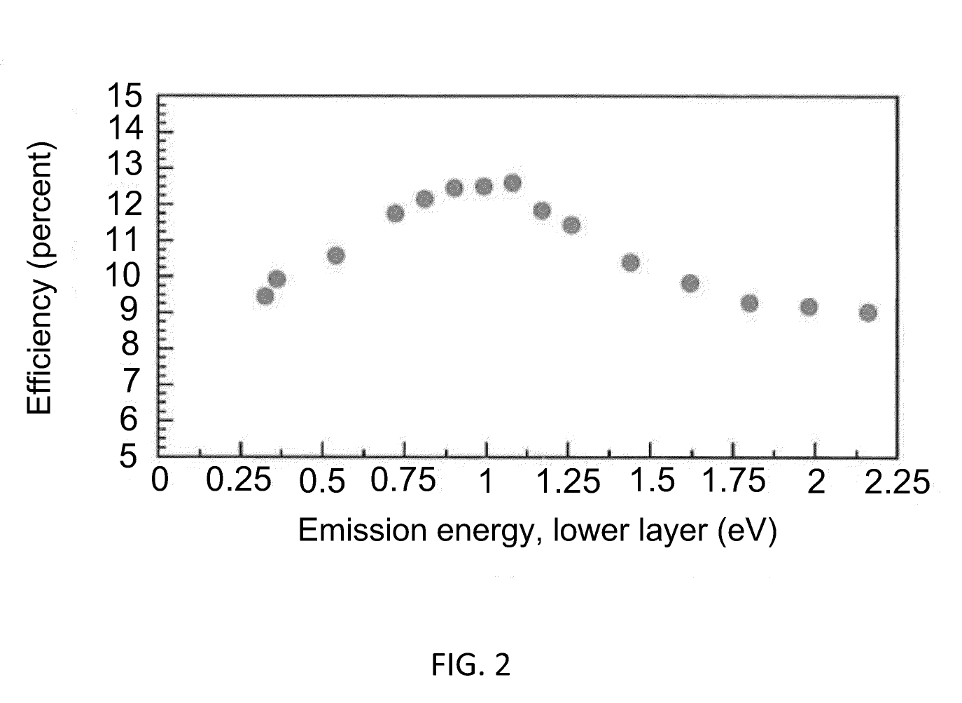

This type of solar concentrator structure 10 reduces the cost of solar energy conversion. This is accomplished by concentrating solar energy from a large area to a small area, reducing the amount of expensive photovoltaic material that is needed. Conventional solar concentrators are based on mirrors or lenses and therefore require direct sunlight. In FIG. 2 is shown the simulated efficiency of one example structure of the LSC 10 incorporating semiconductor nanocrystals as the luminescent material 20, as a function of the energy of the photons emitted by the nanocrystals. The performance of the LSC 10 is quantified in terms of two related numbers: (1) the concentration factor and (2) the efficiency. The goal of designing the LSC 10 is to maximize both of these values. The concentration factor is the ratio between the light intensity at the side of the LSC 10, where the photovoltaic cell 60 is located, to the incident solar radiation 40. If there were no losses in the LSC 10, the concentration factor would be equal to the ratio of the top surface area to the side surface area, known as the geometric concentration factor. In practice, losses in the LSC 10 reduce the concentration factor, so that the real concentration factor is the geometric concentration factor multiplied by the efficiency (the ratio of the optical energy incident on the photovoltaic cell 60 to the solar radiation 40 energy incident on the top of the LSC 10). Losses in the LSC 10 include escape from the light guide 30 at angles higher than the critical angle for total internal reflection, scattering within the light guide 30, absorption by the light-guide material, and absorption of light by the luminescent material 20 that is not followed by emission of light 50 by the luminescent material 20. The importance of all of these factors is multiplied when light emitted by luminescent material 20 in one part of the LSC 10 is reabsorbed by luminescent material 20 in another part of the LSC 10. Minimizing reabsorption by the luminescent material 20, while maintaining high luminescent efficiency, is thus important to achieving high-performance LSCs 10 that can be implemented in practice.

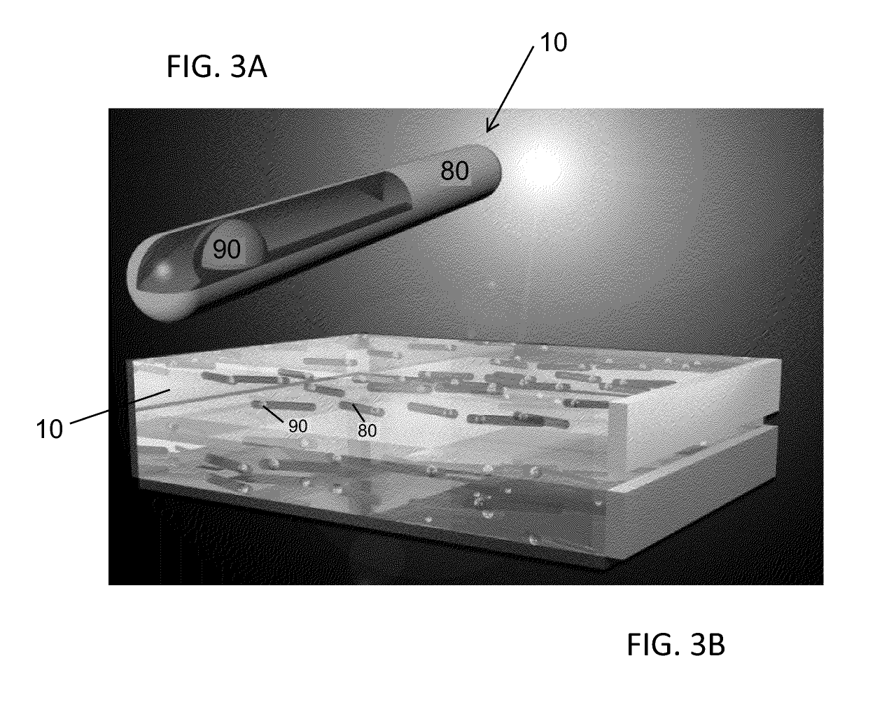

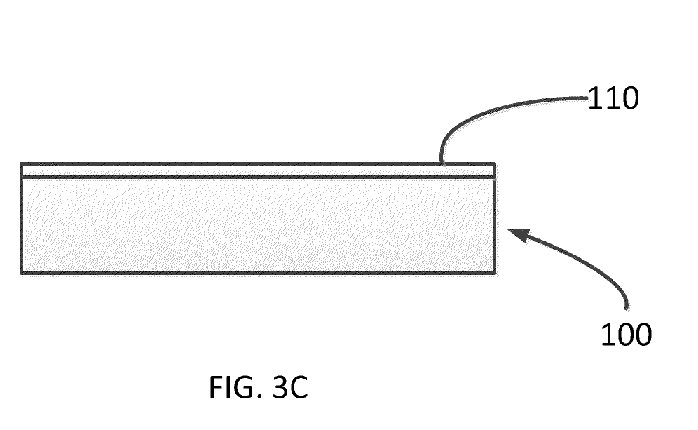

The criteria that the luminescent material 20 must meet in order to produce high-performance LSCs (i.e., with high concentration factors and efficiencies) are (1) low reabsorption of the emitted light 50; (2) stability under sunlight; (3) emission wavelengths that can be tuned to the near-infrared part of the spectrum; and (4) high luminescent quantum yield. Quantum yield is a measure of how efficiently the materials emit the light 50, and is equal to the ratio of the number of photons emitted by the material to the number of photons absorbed by the material 20. Most LSCs 10 to date have used organic dye molecules, which generally have strong reabsorption and limited stability. These problems have been addressed to some extent by molecular engineering, but the ability to absorb and emit at near-infrared wavelengths is still missing. Semiconductor nanocrystals can be designed to emit at nearly any desired wavelength, including the optimal near-infrared wavelengths for LSCs, and nanocrystals can be made stable under sunlight. Typical nanocrystals consist of a single type of semiconductor, sometimes coated with a thin shell of a second type of semiconductor in order to improve their stability. These nanocrystals, though, still have significant reabsorption. In FIG. 3A (also see FIGS. 1C(1)-1C(4)) is shown a schematic illustration (not to scale) of a module of a two-stage form of the LSC 10 based on small-core/large-shell nanocrystals as the luminescent material 20. Small-core/large-shell nanocrystals have the potential to meet all the criteria required for high-performance LSCs 10. The main advance over previously considered nanocrystals is the ability to limit reabsorption. This is possible because absorption is performed by the large shell 80, while emission is performed by the much smaller core 90.

In other embodiments of the invention other applications require wavelength shifting with minimal reabsorption. One key example is extending the detection range of photodetectors, particularly digital imaging devices such as charge-coupled-device (CCD) cameras. These detectors can detect a range of wavelengths that is determined by the type of material used. To extend detection to shorter wavelengths, cameras 100 (see FIG. 3C) can be coated with a coating 110 that contains the luminescent material 20. Again, organic molecules are generally used for this application. The luminescent material 20 absorbs light at wavelengths that are not directly detectable by the photodetector (e.g., ultraviolet light for CCD cameras), and emits at longer wavelengths that are detectable (e.g., visible light for CCD cameras). A limitation of this approach is that the material generally absorbs light at wavelengths close to its emission, so that some of the longer-wavelength light that would normally be detected is lost; that is, the tradeoff for increased detection range is lower detection efficiency within the range that was previously available. Using large-shell/small-core nanocrystals would greatly reduce the unwanted reabsorption, eliminating this tradeoff.

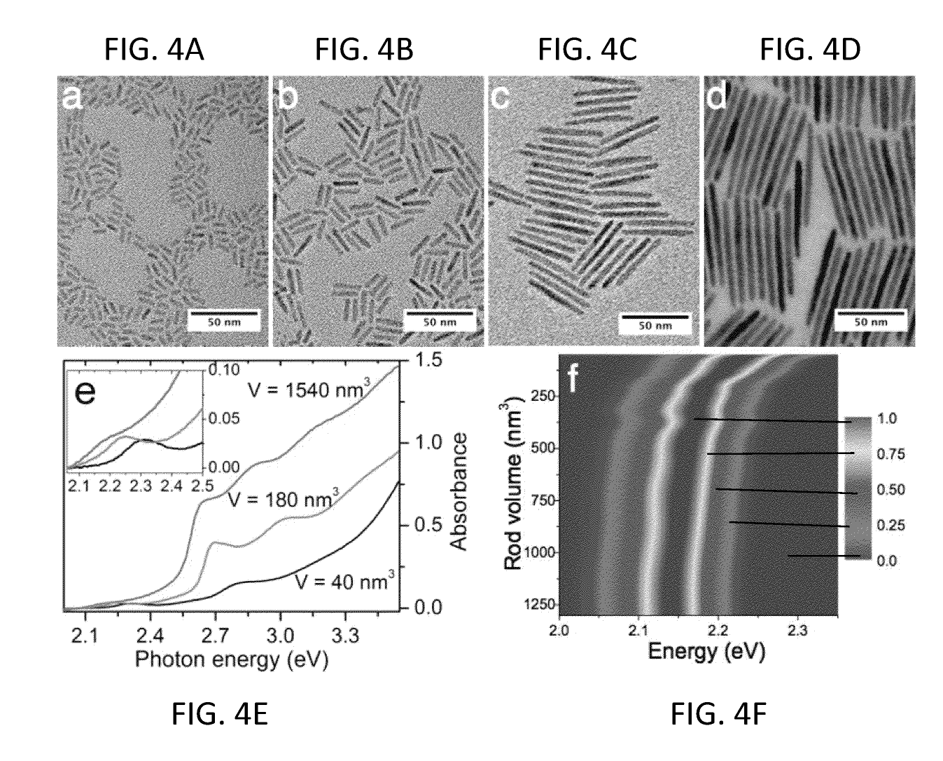

FIGS. 4A-4D show transmission-electron-microscope images of example systems of nanocrystals incorporating small, quasi-spherical CdSe cores in large, rod-shaped CdS shells. These illustrate the basic principles of the small core/large shell concepts. FIG. 4E shows absorption spectra for these nanocrystals; the total volume V of the nanocrystals is indicated. FIG. 4F shows emission spectra of these example systems of nanocrystals as a function of volume. Preparation and testing of this CdSe/CdS structure 70 are described in detail hereinafter. CdSe/CdS core/shell nanocrystals with small, quasi-spherical cores 90 and large, rod-shaped shells 80 demonstrate the materials design principles that are necessary for the optimization of luminescent materials for LSCs 10. In particular, the emission efficiency and the amount of reabsorption depend on the structure of the nanocrystals. More generally and more directed to the invention, the larger shells 80 reduce the importance of reabsorption, because the amount of material in the core 90, which can reabsorb the emitted light, becomes small compared to the amount of material in the shell 80, which does not reabsorb the emitted light 50. However, the larger shells 80 generally lead to lower emission efficiency, which means that there is an ideal shell size that optimizes the tradeoff between emission efficiency and reabsorption. The reasons for decreasing emission efficiency with increasing shell size can be attributed mainly to two factors: (1) a decreasing rate at which photons are emitted, known as the “radiative recombination rate,” due to the delocalization of electrons into the shell 80, and (2) a constant or increasing rate at which energy is lost to heat, known as the “nonradiative recombination rate.” The non-radiative recombination rate is dominated by defects at the interface between the core 90 and the shell 80. The design of a core/shell interface that minimizes defects is thus helpful to the optimization of these materials and the structure 70 for luminescent solar concentrators 10. The decrease in radiative recombination rate, and thus the decreasing emission efficiency, could also be overcome by designing core/shell structures in which electrons in the core 90 have a significantly lower energy than electrons in the shell 80, something that is known as a “type-I band offset.”

In FIG. 5 is shown a series of polymer slabs 120 incorporating CdSe/CdS core/shell nanorods with different dimensions, serving as a prototype multi-stage LSC 10. This is only an example of how the LSC 10 can be structured. Below is described one preferred embodiment of the CdSe/CdS core/shell nanorod system.

As noted above the use of small core/large shell nanocrystals can enable formation of an article with substantially improved solar concentrator performance. In order for this performance to provide improved quantum yield (QY), an article of manufacture is constructed with a balance provided between radiative and non-radiative processes, such as non-radiative recombination. An example of the LSC 10 concept can be demonstrated by the CdSe (core)/CdS shell form of the structure 70 which has been manufactured. While not limiting the scope of the invention, the following describes various features which can be considered in forming various preferred embodiments. One important factor in determining recombination rates in the example CdSe/CdS article is the spatial extent of the carriers, that is, whether the electrons and holes are localized within the CdSe core or are delocalized throughout the nanorods. It is generally accepted that the lowest-energy hole states are confined to the core because the valence-band-edge energy is significantly higher in CdSe than that in CdS. On the other hand, there is uncertainty in the art with regard to whether the lowest-energy electrons are also localized in the core, reflecting what is known as type-I band alignment, or whether they are delocalized throughout the nanorods (NRs), known as quasi-type-II band alignment. Direct measurements of conduction band offsets using scanning tunneling microscopy have indicated a difference of 0.3 eV, leading to the conclusion of type-I band offset in the rods studied. Multiexciton spectroscopy suggested a transition from type-I electron localization to quasi-type-II electron delocalization when the CdSe core is smaller than 2.8 nm in diameter. Exciton localization has also been directly imaged using near-field techniques. However, numerous prior art optical measurements and electronic structure calculations support quasi-type-II band offsets for CdSe/CdS core/shell nanorods. The success of photocatalytic hydrogen production using CdSe/CdS nanorods with Pt tips also strongly suggests that electrons are delocalized in the CdS shells before being transferred to the Pt tips.

To illustrate basic concepts of the small core/large shell structure, the QYs of CdSe/CdS NRs provide an understanding of the type of electron localization/delocalization present in these NRs. Thus, examples were evaluated and photophysical processes were determined by (1) tuning the shell size while keeping the core size fixed and (2) changing the core size in the range from 2.0 to 5.0 nm. No significant trapping of electrons or holes is observed (as opposed to trap-mediated electron—hole recombination), regardless of nanoparticle volume. Radiative decay rates were quantitatively correlated with the rod volume, regardless of the size of the core, indicating that all of the nanorods studied exhibit effective quasi-type-II band alignment. Control of the nanorod volume is thus a preferred method for controlling QY, and high yields were obtained for example systems of relatively small CdS shells to be shown in more detail hereinafter.

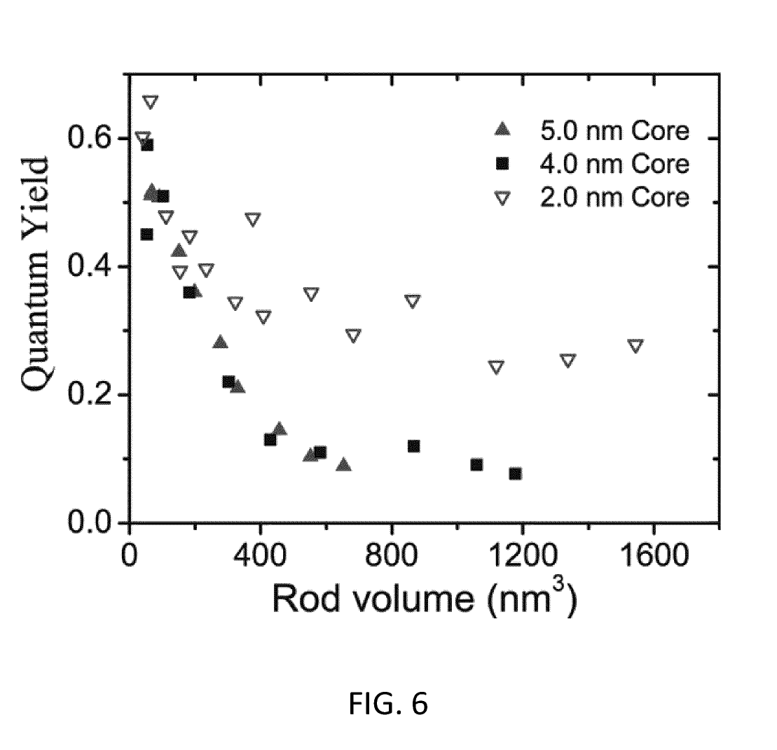

Photoluminescent QYs were determined of CdSe/CdS NRs for different volumes of CdSe cores and CdS shells. NRs with core sizes of 2.0, 4.0, and 5.0 nm were synthesized following a modification of the seeded-growth procedure previously reported (see Example I hereinafter). The larger cores are prolate spheroids; in this case, “core size” is used to refer to the larger of their two diameters. QYs were determined (see FIG. 6) by exciting the shell at 2.76 eV (450 nm), thereby obtaining values that are more relevant for applications such as luminescent solar concentrators. The absorption at this photon energy by the CdS shells is between 5 and 50 times larger than the absorption by the CdSe cores (see below), so direct absorption into CdSe is neglected. As shown in FIG. 6, increasing the size of the rod results in lower QY. Here, rod size is described in terms of the total volume of the core/shell particle because we found that this volume uniquely dictates radiative recombination rates (see below). For NRs with a core size of 2.0 nm, the QY decreases relatively slowly with the rod volume, as compared to NRs with 4.0 and 5.0 nm cores.

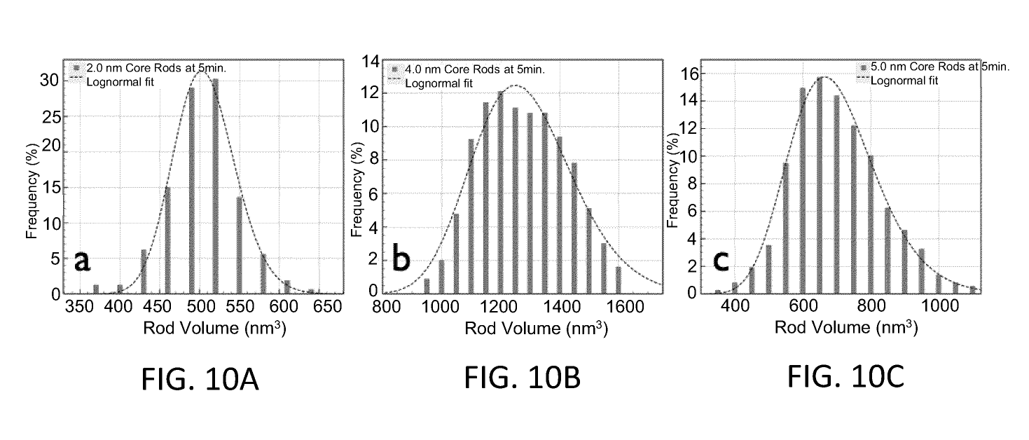

To determine the mechanisms responsible for these size-dependent QYs and for the differences between NRs with different core sizes, the steady-state and time-resolved optical absorption and emission properties of the NRs were evaluated. As mentioned hereinbefore, FIGS. 4A-4F illustrate the steady-state properties for CdSe/CdS core/shell NRs with 2.0 nm CdSe cores. Corresponding data for NRs with 4.0 and 5.0 nm cores show the same trends. In order to correlate the optical properties to the nanoparticle structures, the NR dimensions were measured from TEM images, such as the ones shown in FIGS. 4A-4D. Full information about the NR dimensions for all of the measured samples is given in Table 1 of Example I, and distributions of NR volumes are illustrated in FIGS. 10A-10C of Example I. FIG. 4E shows absorption spectra for three particular NR samples; the peaks at approximately 2.7 and 2.2 eV are the 1S transitions of CdS and CdSe, respectively. As expected, NRs with larger volumes show more dominant absorption of CdS for photon energies above 2.7 eV. FIG. 4F shows a contour plot of emission spectra for NRs with different rod volumes. The emission peak at approximately 2.15 eV comes purely from the CdSe cores.

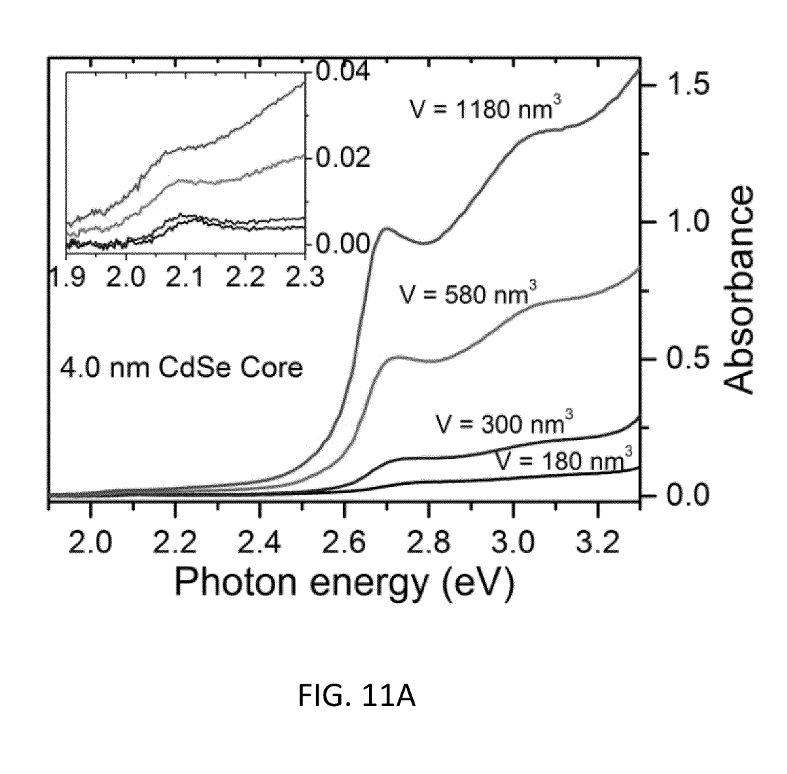

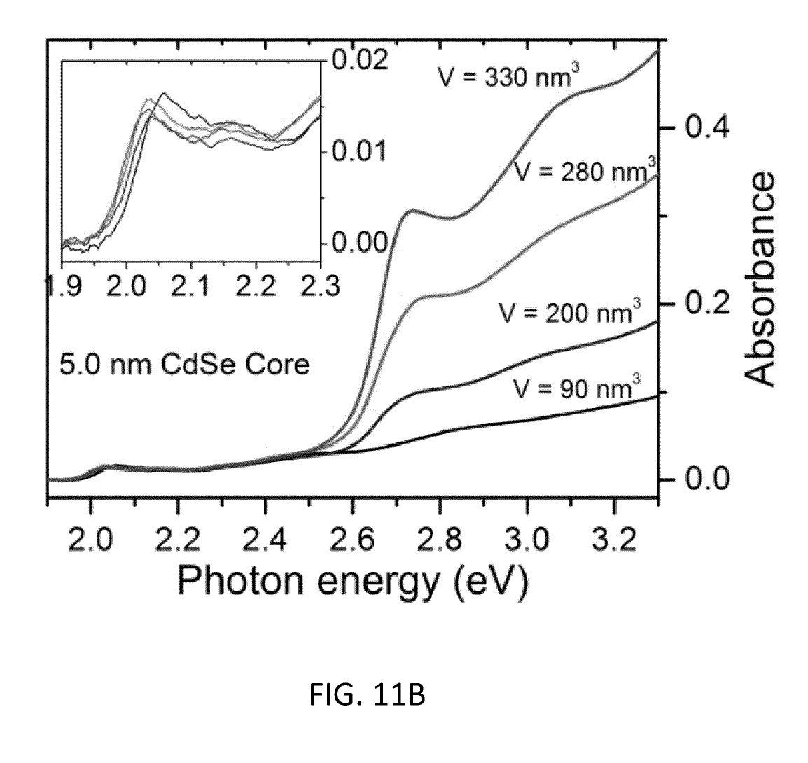

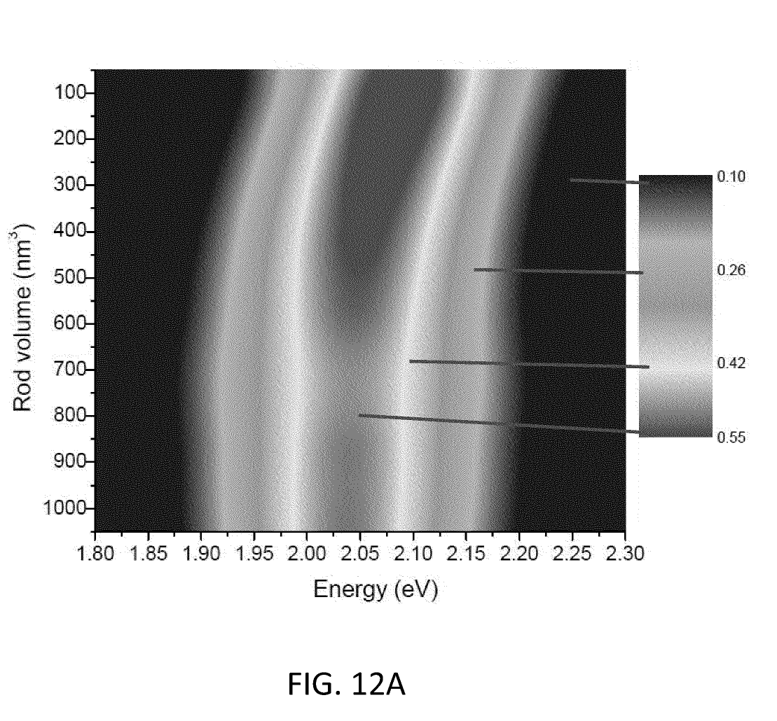

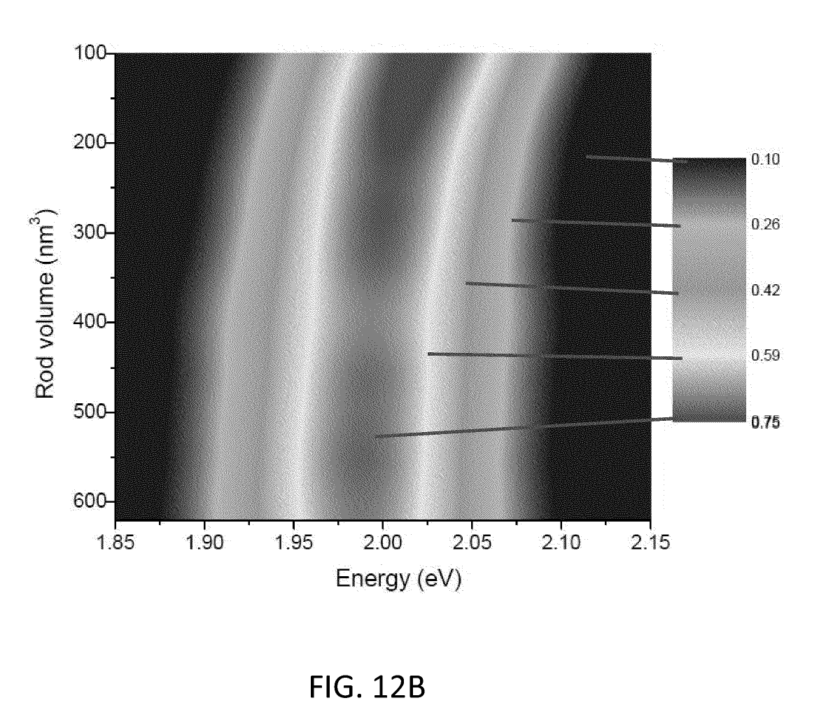

Both the absorption and emission spectra show a progressive decrease of the CdSe transition energy with increasing rod volume. This red shift is typical for a carrier that is delocalized across the entire nanorod, reflecting a decrease in the quantum confinement energy. Similar results are obtained for NRs with 4.0 and 5.0 nm cores (see FIGS. 11A and 11B of Example I), indicating that all NRs examined herein have similar carrier delocalization. Also note the emission spectra of FIGS. 12A and 12B for these 4.0 and 5.0 nm nanorods.

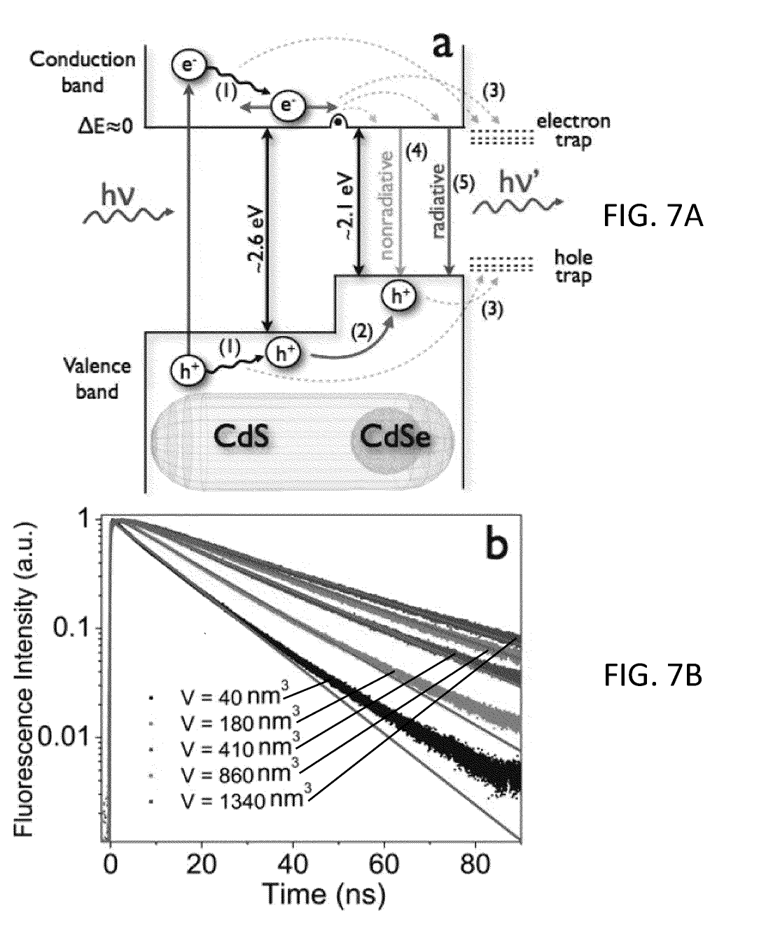

The absorption and emission spectra (FIGS. 4E and 4F) therefore indicate that the electron or hole or both are delocalized throughout the NRs. The valence band offset between CdSe and CdS is known to be large though, meaning that the ground-state hole wave function must be localized in the CdSe core. By contrast, the effective conduction band offset is small or 0, so that the electron wave function can extend into both materials. In other words, the absorption and emission spectra suggest a quasi-type-II band structure of the NRs, as shown in FIG. 7A.

Also shown in FIG. 7A are the various processes that can follow photo-excitation of an electron-hole pair above the CdS band gap energy. In order from fastest to slowest, they are (1) electron and hole relaxation to the band edges, (2) hole transfer to the core, (3) trapping of an electron or hole, meaning transfer of a single carrier to a localized state that quenches luminescence, with the other carrier remaining in its original state, (4) nonradiative recombination of band-edge carriers, and (5) radiative recombination of band-edge carriers. Processes (3) and (4) can result in loss of the PL QY. The term “trapping” refers exclusively to transfer of a single carrier from a conduction band or valence band state to a trap state; trap-mediated processes that result in the annihilation of an electron-hole pair by contrast, are included in the category of nonradiative recombination. All of our experiments were performed in the low-excitation limit, where at most one electron-hole pair at a time is created within the nanocrystal, so that Auger decay and other multi-exciton processes can be neglected (see Example I details).

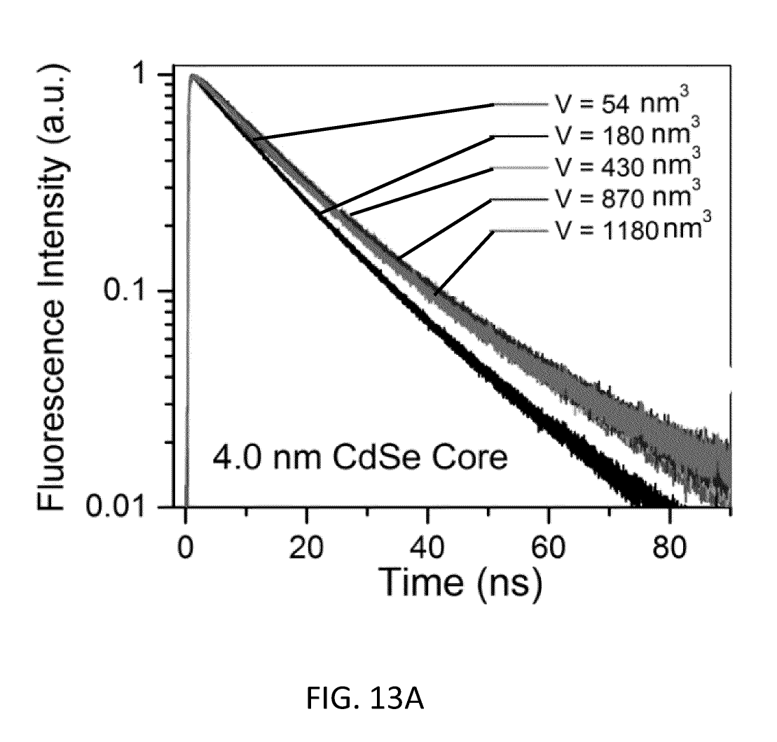

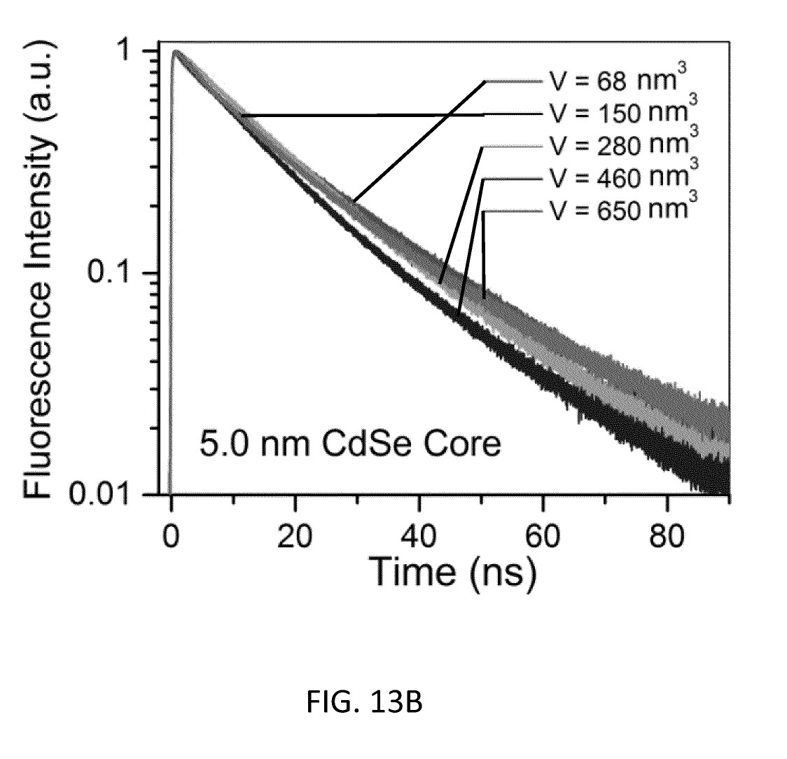

In order to gain insight into the single-exciton processes, we measured PL decay dynamics, exciting the samples with a frequency-doubled Ti:Sapphire laser (excitation energy of 3.1 eV) and using a time-correlated single-photon counting apparatus for time-resolved detection of emission. FIG. 7B shows the PL decay dynamics for CdSe/CdS NRs with 2.0 nm cores; corresponding data for 4.0 and 5.0 nm cores are given in the Supporting Information (See FIGS. 13A and 13B in Example I). The PL decay rate gradually decreases as the nanorod volume increases. For all of the samples measured, over 90% of the PL decay can be described by a single exponential. Carrier trapping is expected to lead to multi-exponential decay, with a fast decay component corresponding to the trapping rate; this has been observed, for example, when electron- or hole-trapping molecules have been deliberately adsorbed onto nanocrystal surfaces. One can thus conclude that carrier trapping in these core/shell nanorods is negligible, so that nearly every photoexcited electron-hole pair relaxes to the band-edge state and then recombines either radiatively or nonradiatively. Deviation from single exponential is greatest for the smallest rods; if surface trapping were responsible for nonexponential decay, it would be expected to be more significant for the larger rods, which have larger surface areas. Note also that closely related “giant” nanocrystals with CdSe cores and thick, spherical CdS cores have been shown to have strongly suppressed blinking behavior, consistent with the lack of surface trapping in these systems. These nanocrystals have also been observed to exhibit single-exponential PL whose decay rate decreases with increasing shell thickness. The measured PL lifetimes are more sensitive to the amount of CdS shell material in the spherical nanoparticles, pointing to the importance of shape in determining the emission properties of these core/shell nanoparticles.

In addition, the nearly single-exponential photoluminescence decay suggests a relatively homogeneous distribution of decay rates in each nanorod sample. Given the homogeneity in both the decay rates and rod shapes as shown by TEM (see FIGS. 4A-4D), the measured ensemble-averaged QY and PL decay time represent approximately the parameters of each individual nanorod.

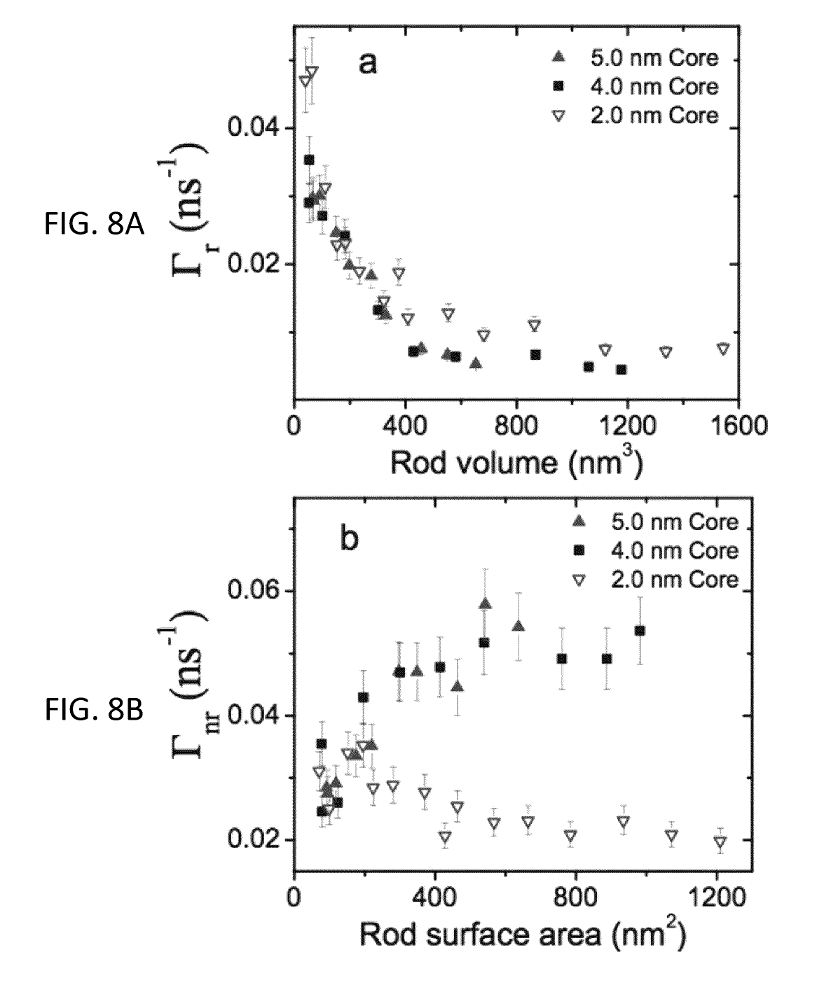

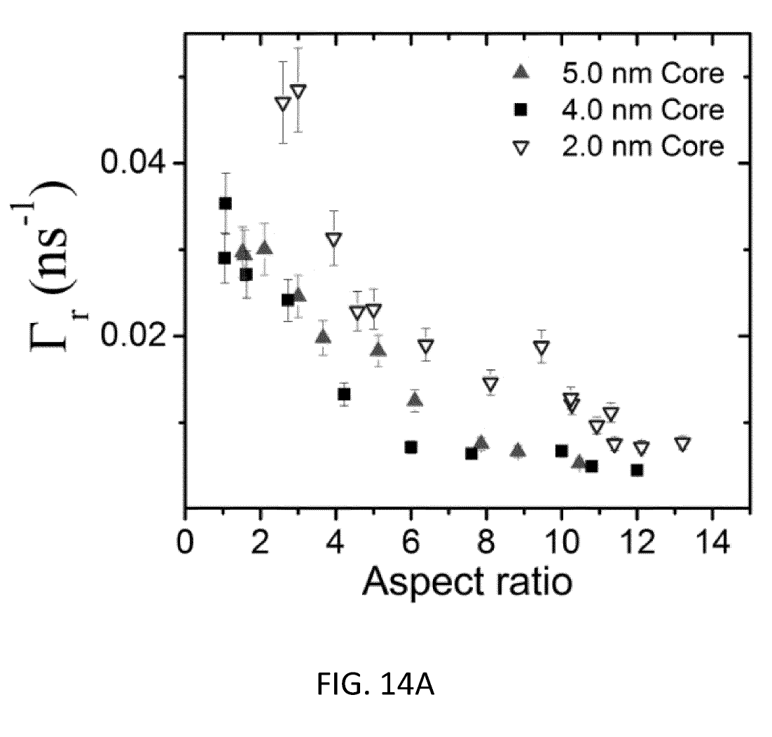

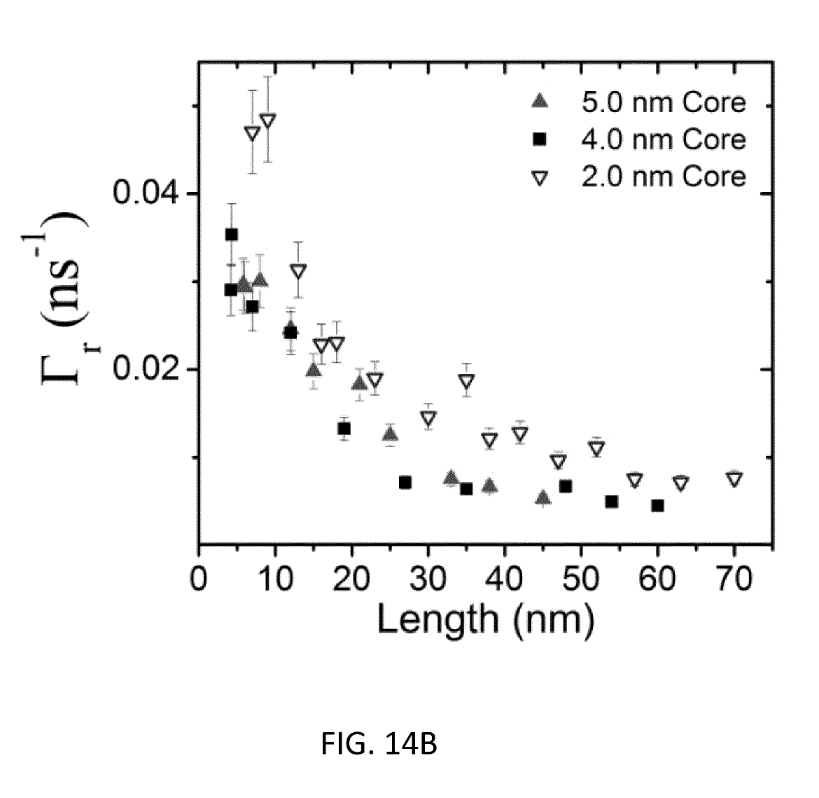

Based on these two conclusions—that there is no significant carrier trapping and that the measured ensemble photoluminescence decay is representative of all of the individual NRs in the ensemble—it is straightforward to calculate radiative and nonradiative decay rates, Γᵣ and Γₙᵣ, based on the measured QYs and PL lifetimes:

$$η = \frac{{Γ}_{r}}{{Γ}_{r} + {Γ}_{nr}} = {Γ}_{r} \cdot {τ}_{O} \qquad ( 1 )$$

where η is the PL QY and τ_{O} is the observed PL lifetime. We use the 1/e decay time to approximate τ_{O} (i.e., the time at which the PL signal has decayed from its maximum value by a factor of e); full results are given in Table 1 of Example I. FIG. 8A shows the radiative decay rates determined in this way as a function of NR volume. The radiative decay rate decreases as the volume increases, following the same universal trend regardless of the different core sizes (2.0, 4.0, and 5.0 nm). Plots of radiative decay rates versus aspect ratios or lengths of NRs do not yield the same universal scaling (see FIGS. 14A and 14B in Example I). The observed scaling of the radiative decay rate with nanorod volume is evidence that the overlap between the electron and hole wave functions decreases as the rod volume increases, indicating that the electron is delocalized throughout the entire NR. In other words, the universal behavior is compelling evidence for the quasi-type-II character of those core/shell heterostructures, regardless of core size. This scaling is also consistent with a simple calculation of electron-hole overlaps for spherical core-shell systems. Although the dependence of radiative decay rate on volume is nearly identical for all of the samples studied, there is a small difference at larger volumes between the samples with 4.0 and 5.0 nm cores and the samples with 2.0 nm cores. This deviation is most likely due to the greater heterogeneity of the samples with larger cores, resulting in slightly nonexponential decays and thus less accurate determination of radiative rates from exponential fits (see FIGS. 13A and 13B in Example I).

FIG. 8B shows the nonradiative decay rate as a function of the surface area of the rods; in this case, we choose surface area rather than volume as the relevant geometrical parameter because it should be proportional to the number of surface defects. The nonradiative decay rates for NRs with 2.0 nm CdSe cores depend only weakly on the surface area. For NRs with 4.0 and 5.0 nm cores, by contrast, the nonradiative decay rates increase dramatically with the rod surface area. The additional nonradiative pathways that are present in the NRs with larger cores may be related to surface states, to defects in the bulk of the semiconductor, or to strain-induced defects at the CdSe/Cds interface.

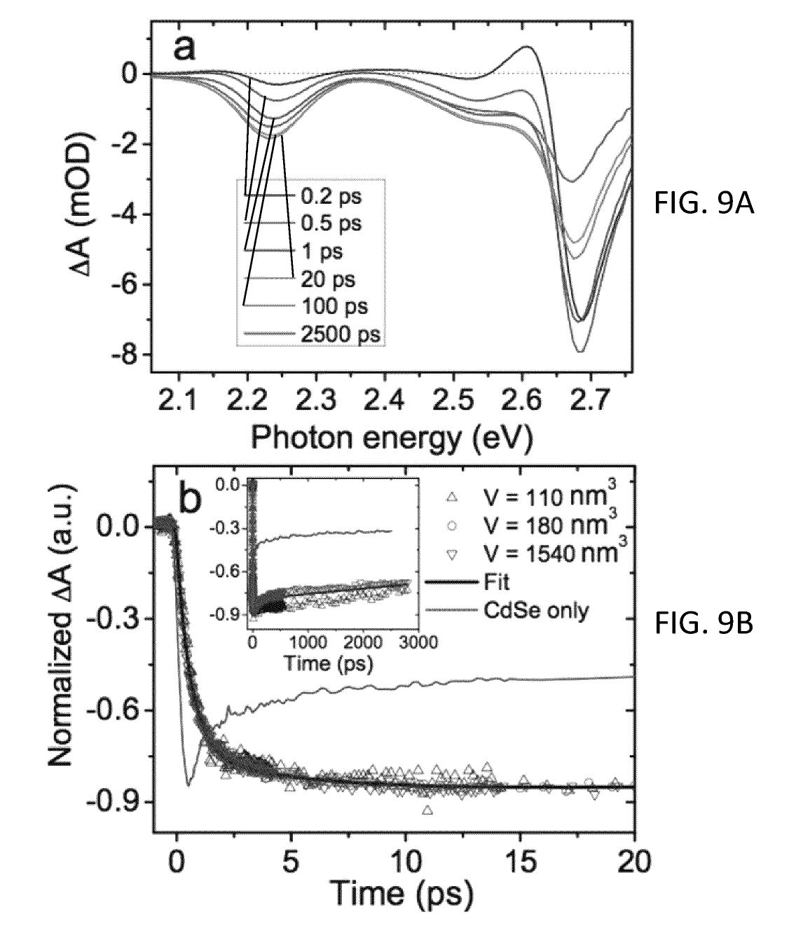

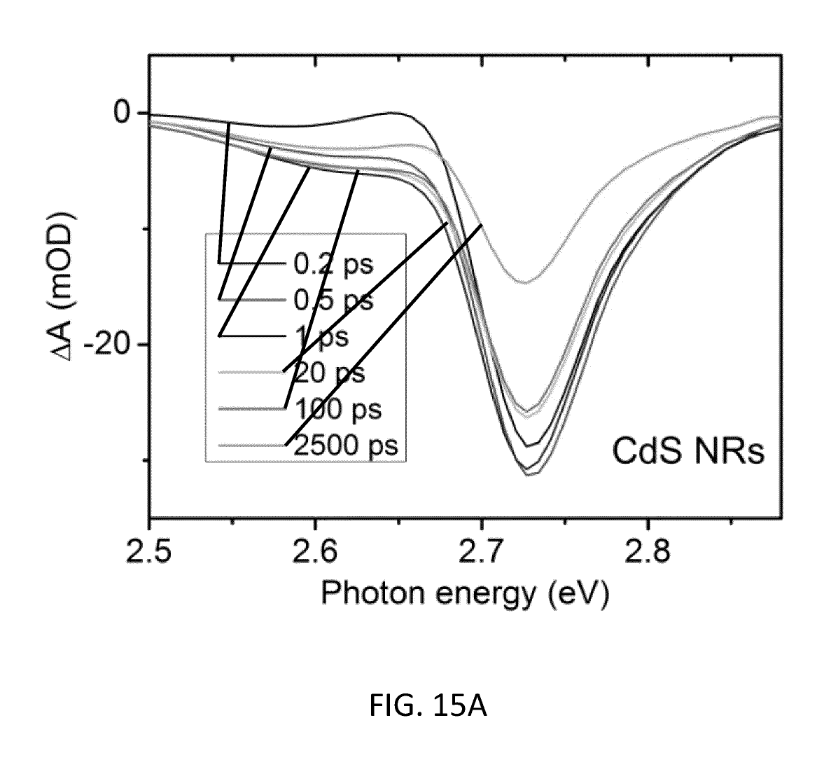

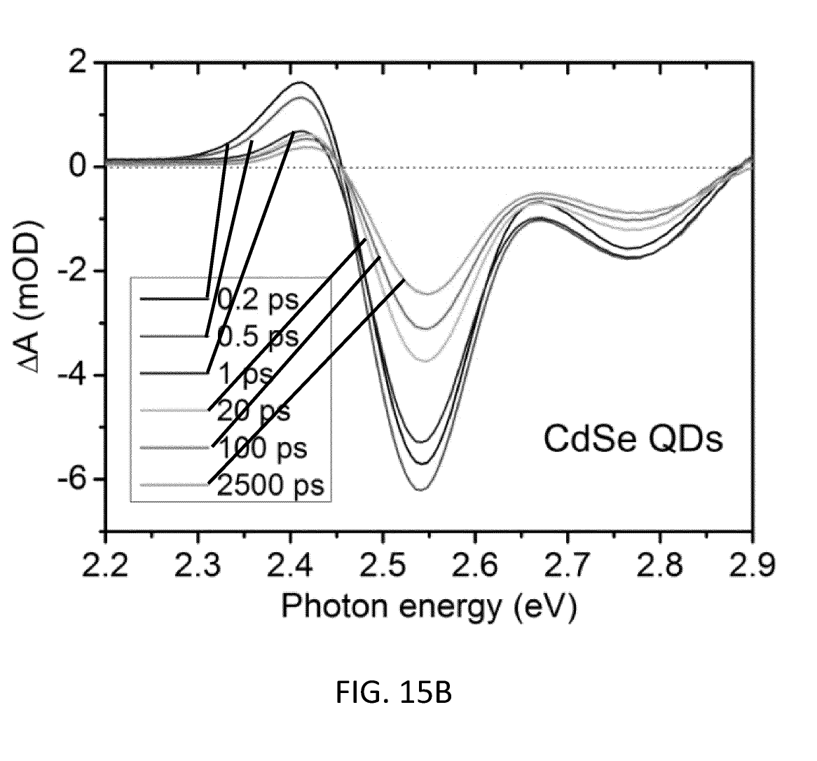

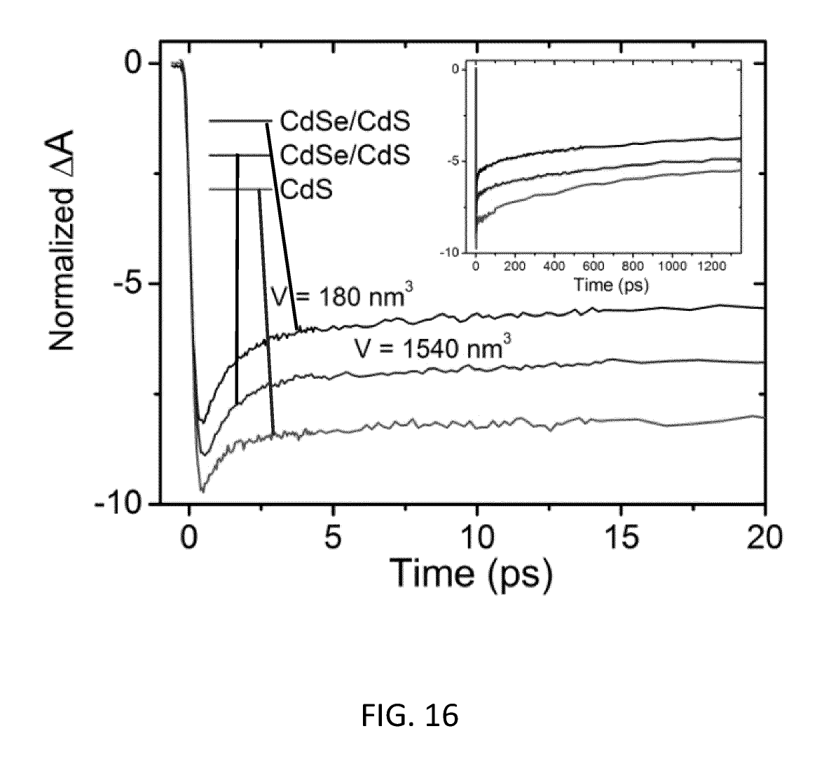

The principal basis for these preferred embodiments—quasi-type-II band alignment and the absence of significant electron or hole trapping in the NRs—are also supported by transient absorption (TA) spectroscopy. We again illustrate the properties of all of the samples with data from CdSe/CdS NRs with 2.0 nm cores. FIG. 9A shows the transient absorption spectra for NRs with an average volume of 180 nm³, following excitation of the CdS shell at 3.10 eV (400 nm). The CdS bleach signal at approximately 2.68 eV reaches its maximum within 0.5 ps due to carrier relaxation and state filling. Similar behavior can be seen in the transient spectra and bleach dynamics of pure CdS NRs under the same experimental conditions (see FIGS. 15A, 15B and 16 in Example I). Because the state-filling-induced bleach signal is dominated by the electron, the similarity suggests similar transient electron dynamics and delocalization in CdSe/Cds and CdS NRs. Further evidence that the bleach signal at 2.68 eV for the CdSe/Cds core/shell nanorods comes from the CdS shell is provided by the 2:1 ratio of this signal at 2500 ps to the CdSe 1S bleach signal at 2.25 eV; if the signal came from the 1P transition of CdSe, it would be much smaller than the CdSe 1S transition, as observed for pure CdSe nanocrystals (see FIGS. 15A and 15B in Example I). The large bleach at 2.68 eV is thus direct evidence of state filling in CdS, and its large value at 2500 ps is evidence that the electron remains delocalized in the shell well after the initial excitation. This provides further support for the quasi-type-II character of these heterostructures.

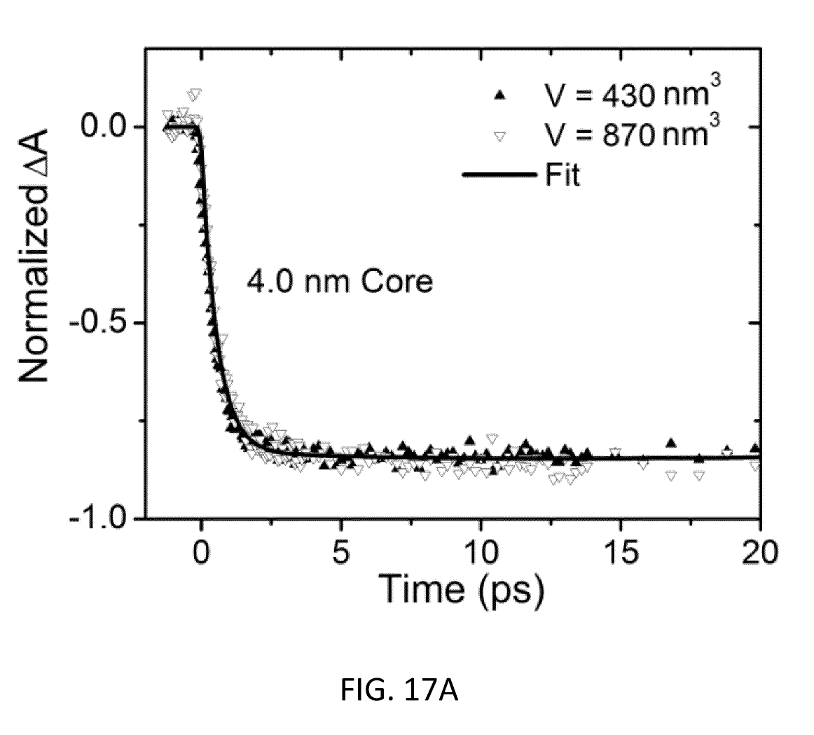

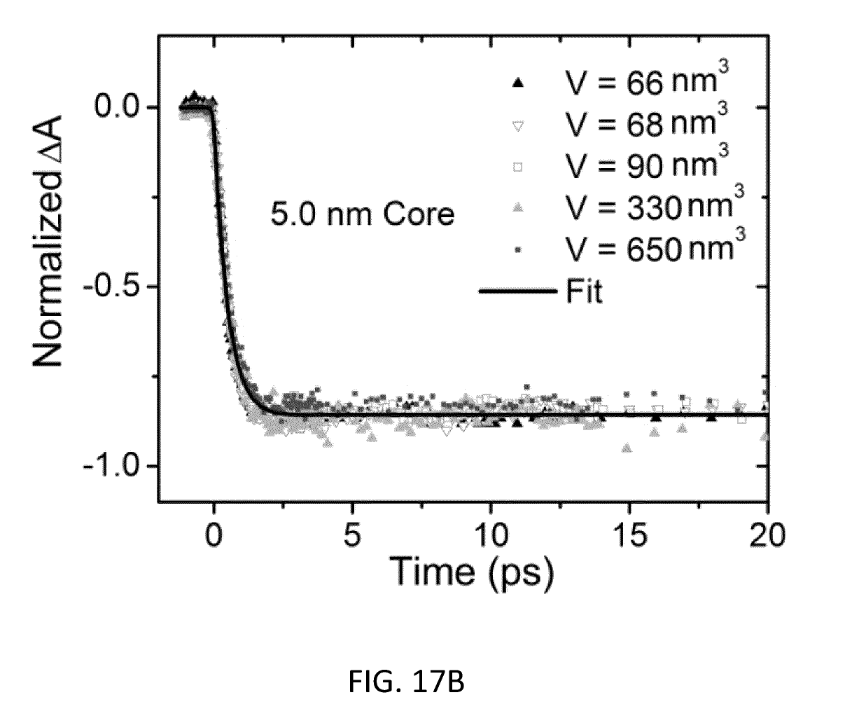

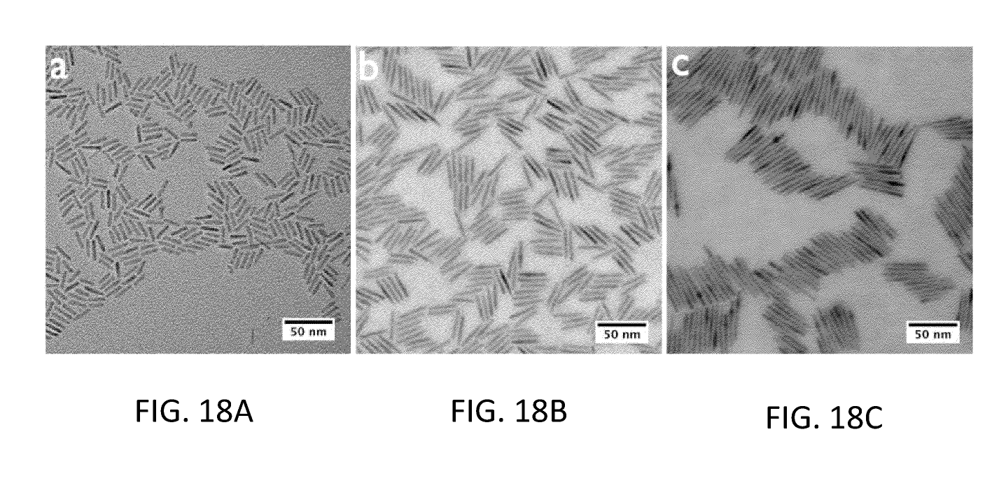

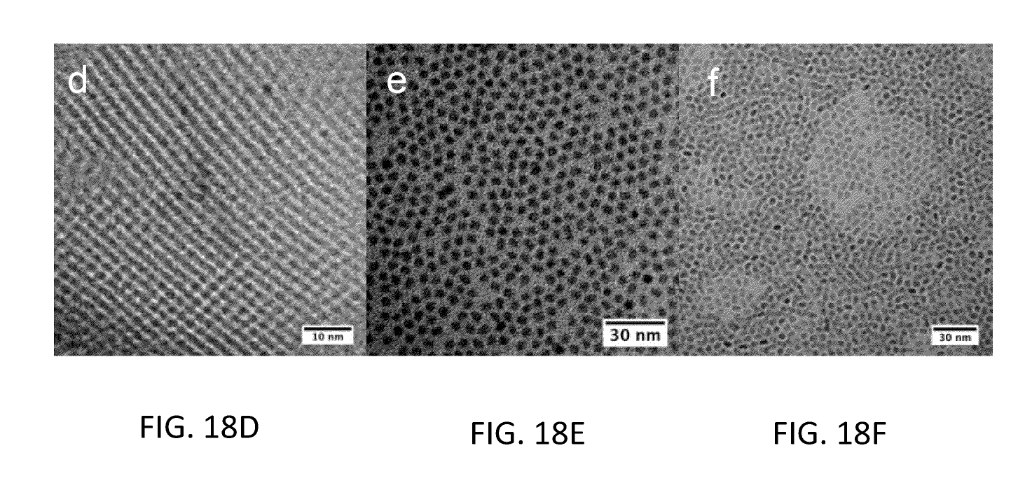

Unlike the ultrafast growth of the CdS bleach, the bleach of the CdSe 15 transition at 2.25 eV grows relatively slowly, reaching its maximum in 10-20 ps. This slow growth of the CdSe bleach is distinctly different from the fast growth in pure CdSe QDs, which occurs in less than 0.5 ps and is due to relaxation of high-energy carriers (FIG. 9B and FIGS. 15A and 15B in Example I). The relatively slow growth in CdSe/CdS core/shell NRs is attributed to hole transfer from CdS to CdSe (process (2) in FIG. 7A). FIG. 9B shows the dynamics of hole transfer for NRs with different volumes but the same 2.0 nm CdSe core. The hole transfer dynamics appears to be independent of rod volume from approximately 100 to 1500 nm³. The dynamics can be fit with two exponentials with time constants of 0.62±0.02 and 4.5±0.3 ps, consistent with previously reported hole-transfer rates; similar results are obtained for NRs with 4.0 or 5.0 nm cores (FIGS. 17A and 17B in Example I). The fact that the measured time constants are independent of shell size indicates that there are no size-dependent hole-trapping processes that compete with hole transfer. The time constants can be compared to those for carrier transfer in true type-II nanocrystal heterostructures, such as ZnSe/CdS “nanobarbells” consisting of CdS nanorods with ZnSe tips. In these structures, transfer of photo-excited electrons from ZnSe to CdS is fast, occurring in less than 1 ps, whereas hole transfer from CdS to ZnSe is much slower, taking about 100 ps. The rate of hole transfer from CdS to CdSe in our core/shell nanorods is intermediate between these values, reflecting the different driving energies for the carrier-transfer processes and the different geometry of the heterostructures.

The inset in FIG. 9B shows decay dynamics for the CdSe 1S exciton after hole transfer. For pure CdSe nanoparticles, the signal rapidly decays to less than half of its initial value due to carrier trapping; by contrast, in CdSe/CdS NRs, the signal shows no rapid decay and is only about 15% less than its maximum value even after 2500 ps. This indicates that there is no significant carrier trapping in the CdSe/CdS core/shell NRs on nanosecond time scales, consistent with the PL decay measurements. This further validates the use of Eq. (1) to estimate radiative and nonradiative decay rates.

The observation that radiative decay rates are dictated by rod volumes provides strong evidence for quasi-type-II effective band alignment in all of the NR structures that were studied, which is further supported by the steady-state emission spectra and transient absorption data.

The photophysical properties have been provided for CdSe/CdS NRs and related to photoluminescence QY. Transient absorption and time-resolved luminescence measurements indicate no significant trapping of electrons or holes. The hole is localized into the core within 10 ps, with a transfer rate that is independent of the size of the shell, and the electron remains delocalized in the shell. Radiative decay rates can be quantitatively correlated with the rod volume regardless of the size of the CdSe core for core sizes in the measured range from 2.0 to 5.0 nm.

The following non-limiting Example describes synthesis of a small-core/large-shell NC structure that would allow for improved LSC performance and measurements taken on the NCs described hereinbefore.

### Example I

### A. Starting Chemical Compounds Used

CdO (Sigma-Aldrich, 99%), n-propylphosphonic acid (PPA, Sigma-Aldrich, 95%), triocytylphosphine oxide (TOPO, Sigma-Aldrich, 99%), octa-decyl-phosphonic acid (ODPA, PCI Synthesis, 97%), triocytylphosphine (Fluka, 90%), selenium (Aldrich, 98%), sulfur (Sigma-Aldrich, 99%), n-propylphosphonic acid (PPA, Aldrich, 95%), dodecanoic acid (Sigma-Aldrich, 99%), and octylamine (Aldrich, 99%) were used for the synthesis of nanoparticles (NPs).

### B. Synthesis of CdSe Seeds

CdSe seeds were synthesized in 50 ml three-neck flask using a Schlenk-line approach. TOPO (3.0 g), ODPA (0.308 g), and CdO (0.060 g) were mixed, heated up to 150° C., and kept under vacuum for 2 h. The reaction solution was then heated up under nitrogen to 300° C. at approximately 7° C./min. The reaction solution became transparent, indicating the formation of Cd-ODPA complexes. Next, 1.5 g of TOP was rapidly injected into the reaction flask. TOP-Se solution (0.058 g Se+0.360 g TOP) was injected; for the synthesis of 2.0-nm, 4.0-nm, and 5.0-nm seeds, the injection temperatures were 380° C., 370° C. and 360° C., respectively. For 2.0-nm seeds, the reaction was quenched immediately after the injection of TOP-Se by injection of 5 ml of room-temperature toluene. For 4.0-nm and 5.0-nm seeds the reaction solution was kept at high temperature for 330 s. After the solution cooled down to room temperature, the seeds were precipitated by adding ethanol and centrifuging; this washing step was repeated twice. Finally, the seeds were re-dissolved in toluene and stored inside a glove box under nitrogen atmosphere.

### C. Synthesis of CdSe/CdS Core/Shell Nanorods

CdO (0.207 g), PPA (0.015 g), TOPO (2.0 g), and ODPA (1.2 8 g) were mixed in a three-neck flask. The solution was degassed, heated up to 150° C., and kept under vacuum for 2 h. The solution was then heated up to 340° C. and kept at that temperature for 15 min. Next, 1.5 g of TOP was injected. After stabilization of the temperature at 340° C., TOP-S solution (0.05152 g S+0.5957 g TOP) and TOP-seeds solution (2 mg CdSe seeds+0.5 ml TOP) were rapidly injected in the flask. The reaction time was varied from 1 to 10 minutes. After the synthesis, the CdSe/CdS nanorods were precipitated with methanol (20 ml), and were then re-dissolved in toluene (5 ml) containing dodecanoic acid (0.125 g) and octylamine (0.390 g).

### D. Synthesis of CdS Nanorods

CdO (0.207 g), PPA (0.015 g), TOPO (2.0 g), and ODPA (1.28 g) were mixed in a three-neck flask. The solution was degassed, heated up to 150° C., and kept under vacuum for 2 h. The solution was then heated up to 340° C. and kept at that temperature for 15 min. Next, 1.5 g of TOP were injected. After stabilization of the temperature at 340° C., TOP-S solution (0.05152 g S+0.5957 g TOP) was rapidly injected in the flask. After 2 minutes, the reaction was quenched by injection of 5 ml of room-temperature toluene. The nanorods were then precipitated with methanol (20 ml), and re-dissolved in toluene (5 ml) containing dodecanoic acid (0.125 g) and octylamine (0.390 g).

### II. Optical Measurements

### E. Absorption, Emission, and Quantum Yield

Optical absorption and photoluminescence measurements were performed on nanorods in toluene solution (described above) using UV-Vis (Cary-50) and fluorescence (LS-55, Perkin-Elmer) spectrometers, respectively. The photoluminescence (PL) quantum yields (QYs) of nanorods were determined by comparison to a standard sample of Coumarin 153 in ethanol using the following equation:

$${η}_{x} = {η}_{st} \frac{{S}_{x}}{{S}_{st}} \frac{( 1 - {10}^{- {A}_{st}} )}{( 1 - {10}^{- {A}_{x}} )} {( \frac{{n}_{x}}{{n}_{st}} )}^{2} ,$$

where ηₓ and ηₛₜ=0.53 are the QYs of nanorods and the standard sample, respectively; Sₓ and Sₛₜ are the integrated areas of the emission peaks of the nanorods and the standard sample, respectively; Aₓ and Aₛₜ are the absorbances of the nanorods and the standard sample, respectively, at the excitation wavelength of 450 nm (2.76 eV); and nₓ=1.494 and nₛₜ=1.360 are the indices of refraction of the toluene and ethanol solvents, respectively. The optical densities at 450 nm of all samples were controlled to be within the range 0.03-0.05, in order to minimize the inner filter effect. The error bar of all the measured ηₓ is estimated to be less than ±0.02.

### F. Photoluminescence Decay

Photoluminescence decay kinetics were measured using a time-correlated single-photon counting (TCSPC) method. The nanorods were excited by frequency-doubled pulses from a mode-locked Ti:sapphire laser (Coherent Mira, 400 nm excitation wavelength, 5 MHz repetition rate). The excitation beam was focused into toluene solutions of nanorods by a 10× air objective, and the same lens was used to collect the emission. The emission was separated from reflected laser light with a dichroic mirror and two bandpass filters, and was then detected by a single-photon counter (Micro Photon Devices). Output pulses from the detector were sent to the input channels of a time-correlated single-photon counting module (PicoQuant PicoHarp 300). The arrival time of every photon is recorded relative to the corresponding excitation-laser pulse. The histogram of delay times between excitation and photon detection gives the photoluminescence decay curve. The instrument response function of the TCSPC apparatus is estimated to be 0.12 ns.

### G. Transient Absorption

Ultrafast transient absorption measurements were carried out using a Helios spectrometer (Ultrafast Systems). An amplified Ti:Sapphire pulse (800 nm, 120 fs, 0.5 μJ/pulse, 1.67 kHz repetition rate Spectra-Physics Spitfire Pro) was split into two beams. The first beam, containing 10% of the power, was focused into a sapphire window to generate a white light continuum (440 nm-750 nm), which serves as the probe. The other beam, containing 90% of the power, was sent into an optical parametric amplifier (Spectra-Physics TOPAS) to generate the pump beam. After the pump beam passes through a depolarizer, it is focused and overlapped with the probe beam at the sample. The pump power was chosen to be 20 nJ/pulse; at these pump energies, we observed no power-dependent kinetic features corresponding to multiexciton decay, indicating that each nanorod absorbs on average less than one photon per pulse. Pump wavelengths of 400 nm and 450 nm gave identical kinetics of hole transfer; we therefore report results with 400-nm excitation, in order to increase the signal (due to larger sample absorbance at 400 nm) and to match the conditions in the photoluminescence-decay experiments. Absorption spectra of the samples were found to be identical before and after the transient-absorption experiments, indicating that the measurements do not damage the samples.

### III. Nanorod Properties

### H. Dimensions

Dimensions of the nanoparticle samples were determined from transmission-electron-microscope (TEM) images. Three different CdSe core sizes were synthesized. The smallest cores were nearly spherical, with diameters of 2.0 nm. The two larger cores were approximately prolate spheroids with equatorial diameters of approximately 3.0 nm and polar diameters of 4.0 nm and 5.0 nm, respectively; we refer to these cores according to their larger dimensions. Figure S1 shows sample TEM images of CdSe/CdS core/shell nanorods and the three different core sizes. Figure S2 shows sample distributions of nanorod volumes as determined from similar TEM images. The average dimensions and the standard deviations in the volumes are summarized for all the measured nanorod samples in Table S1.

TABLE 1
Measured dimensions and 1/e photoluminescence decay times for CdSe/CdS
core/shell nanorods. The dimensions are determined from TEM images. Errors in the volume
correspond to standard deviations, as measured from the images.

| 2.0 nm core | | | | 4.0 nm core | | | | 5.0 nm core | | | |
|---|---|---|---|---|---|---|---|---|---|---|---|
| | | | PL | | | | PL | | | | PL |
| | | | decay | | | | decay | | | | decay |
| volume | length | diameter | time | volume | length | diameter | time | volume | length | diameter | time |
| (nm³) | (nm) | (nm) | (ns) | (nm³) | (nm) | (nm) | (ns) | (nm³) | (nm) | (nm) | (ns) |
| 40 ± 4 | 7 | 2.7 | 13 | 53 ± 5 | 4.2 | 4.0 | 16 | 66 ± 5 | 5.8 | 3.8 | 17 |
| 64 ± 5 | 9 | 3.0 | 14 | 54 ± 5 | 4.3 | 4.0 | 17 | 68 ± 5 | 6.0 | 3.8 | 18 |
| 110 ± 10 | 13 | 3.3 | 15 | 100 ± 10 | 7 | 4.3 | 19 | 90 ± 10 | 8 | 3.8 | 17 |
| 150 ± 10 | 16 | 3.5 | 17 | 180 ± 15 | 12 | 4.4 | 15 | 150 ± 15 | 12 | 4.0 | 17 |
| 180 ± 10 | 18 | 3.6 | 19 | 300 ± 30 | 19 | 4.5 | 17 | 200 ± 20 | 15 | 4.1 | 18 |
| 230 ± 20 | 23 | 3.6 | 21 | 430 ± 40 | 27 | 4.5 | 18 | 280 ± 30 | 21 | 4.1 | 15 |
| 320 ± 20 | 30 | 3.7 | 24 | 580 ± 60 | 35 | 4.6 | 17 | 330 ± 40 | 25 | 4.1 | 17 |
| 380 ± 20 | 35 | 3.7 | 25 | 870 ± 100 | 48 | 4.8 | 18 | 460 ± 60 | 33 | 4.2 | 19 |
| 410 ± 20 | 38 | 3.7 | 27 | 1060 ± 130 | 54 | 5.0 | 18 | 550 ± 90 | 38 | 4.3 | 16 |
| 500 ± 30 | 41 | 4.0 | 28 | 1250 ± 160 | 60 | 5.0 | 17 | 660 ± 120 | 45 | 4.3 | 17 |
| | | | | 680 ± 40 | 47 | 4.3 | 31 | | | | |
| | | | | 860 ± 50 | 52 | 4.6 | 32 | | | | |
| | | | | 1120 ± 80 | 57 | 5.0 | 33 | | | | |
| | | | | 1340 ± 90 | 63 | 5.2 | 36 | | | | |
| | | | | 1540 ± 110 | 70 | 5.3 | 36 | | | | |

The foregoing description of embodiments of the present invention has been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments, and with various modifications, as are suited to the particular use contemplated.

What is claimed is:

1. An article of manufacture for a luminescent solar concentrator, comprising:
a luminescent material;
a light guide at least one of within which or on which is disposed the luminescent material, the luminescent material absorbing solar radiation and formulated to emit radiation of longer wavelengths than the solar radiation being absorbed; and
a photovoltaic cell for receiving the radiation of longer wavelengths and outputting electrical energy.

2. The article of manufacture as defined in claim 1 wherein the light guide has a refractive index enabling total internal reflection of the longer wavelengths of radiation.

3. The article of manufacture as defined in claim 1 wherein the longer wavelengths comprise an infrared spectral range of wavelengths.

4. The article of manufacture as defined in claim 1 wherein the luminescent material is disposed in a shell disposed in the light guide.

5. The article of manufacture as defined in claim 4 wherein the shell includes a large outer shell and a smaller core disposed in the large outer shell.

6. The article of manufacture as defined in claim 1 wherein the luminescent material comprises nanocrystals.

7. The article of manufacture as defined in claim 5 wherein the smaller core includes luminescent material and is formulated to emit the longer wavelengths.

8. The article of manufacture as defined in claim 1 wherein the luminescent material is formulated to absorb the solar radiation and cause wavelength shifting of emitted radiation relative to the solar radiation.

9. The article of manufacture as defined in claim 6 wherein the nanocrystals are disposed in a plurality of the light guide to form a layered structure.

10. The article of manufacture as defined in claim 1 wherein the luminescent material comprises a heavy metal chalcogenide and a heavy metal compound of a second chalcogenide.

11. The article of manufacture as defined in claim 10 wherein the luminescent material is selected from the group of PbSe, PbS, PbTe, CdSe, CdS, CdTe, ZnSe and ZnS.

12. The article of manufacture as defined in claim 5 wherein the luminescent material comprises a pair of semiconductor materials wherein the small core has a bandgap energy lower than that of the large shell.

13. The article of manufacture as defined in claim 1 wherein the photovoltaic cell is structured to match with the luminescent material to achieve maximum efficiency of energy transfer.

14. The article as defined in claim 10 wherein the luminescent material is chemically adjusted to establish optimum electronic band alignment thereby enabling efficient electronic hole carrier transfer.

15. The article of manufacture as defined in claim 10 wherein the luminescent material is chemically adjusted to minimize at least one of nonradiative recombination, electronic carrier trapping and reabsorption of the longer wavelengths.

16. An article of manufacture for a luminescent material for wavelength shifting, comprising:
an optical medium; and
a luminescent material associated with the optical medium, the luminescent material configured to receive radiation and wavelength shift the radiation for output from the optical medium and optically processing and use of the wavelength shifted radiation.

17. The article of manufacture as defined in claim 16 wherein the optical medium comprises a scintillation detector.

18. The article of manufacture as defined in claim 17 wherein the luminescent material comprises a shell structure disposed in the optical medium.

19. The article of manufacture as defined in claim 18 wherein the shell structure comprises a large outer shell and a smaller core disposed in the outer shell.

20. The article of manufacture as defined in claim 19 wherein the luminescent material is selected from the group of (1) nanocrystals and (2) a rod shaped CdSe, PbSe or PbTe shell with a CdS, PbS or PbS smaller core.
